(19) United States
(12) Patent Application Publication
(10) Pub. No.: US 2006/0252650 A1
(43) Pub. Date: Nov. 9, 2006

(54) Superconducting permanent magnet

(75) Inventors: Tetsuo Oka, Obu-shi (JP); Koshichi Noto, Sendai-shi (JP); Kazuya Yokoyama, Morioka-shi (JP)

Correspondence Address: LOWE HAUPTMAN BERNER, LLP, 1700 DIAGONAL ROAD, SUITE 300, ALEXANDRIA, VA, 22314, US

(73) Assignee: AISIN SEIKI CO. LTD., Kariya-shi (JP)

(21) Appl. No.: 10/554,220

(22) PCT Filed: Apr. 23, 2005
(86) PCT No.: PCT/JP04/05909

§ 371 Date: Oct. 24, 2005

(30) Foreign Application Priority Data
Apr. 25, 2003 (JP) 2003122288

(51) Int. Cl. H01L 39/24

(52) U.S. Cl. 505/100

(57) ABSTRACT

The present invention provides an apparatus generating a magnetic field, coined a “superconducting permanent magnet apparatus,” that magnetize bulk superconductors into pseudo-permanent magnets, which offer a large, usable space having a strong magnetic field. The superconducting permanent magnet apparatus according to this invention includes: a magnetic pole assembly that holds in a thermally insulated condition, a composite bulk composed of a plurality of bulk superconductors which are arranged in parallel with each other within a vacuum vessel. A stand (i) holds at least a plurality of said magnetic pole assemblies each in a predetermined orientation, and (ii) is movable in a condition that said magnetic pole assemblies are mounted thereon. A cooling part of a freezer is mounted on said magnetic pole assembly. A vacuumizing apparatus being a vacuum pump is connected to said magnetic pole assembly via a vacuum pipe. The composite bulk in said vacuum vessel is fixed to a flange of said magnetic pole assembly to which the vacuum vessel is fixed using a resin-based structural member having a heat-insulating property.

### CROSS-REFERENCE TO RELATED APPLICATIONS

The present Application is based on International Application No. PCT/JP2004/005909, filed on Apr. 23, 2004, which in turn corresponds to JP 2003-122288 filed on Apr. 25, 2003, and priority is hereby claimed under 35 USC §119 based on these applications. Each of these applications are hereby incorporated by reference in their entirety into the present application.

### FIELD OF THE INVENTION

The present invention relates to an apparatus generating a magnetic field that enables bulk superconductors—in the superconductive condition thereof—capture a magnetic field, then, that utilizes the bulk superconductors as a magnet.

### BACKGROUND OF THE INVENTION

As a conventional means for obtaining a usable space with a strong magnetic field, disclosed in Patent Document 1 is an apparatus that, while cooling a bulk superconductor by connecting it via a heat conveying member with a cooling part of a freezer, magnetizes the bulk superconductor by applying a pulse magnetic field.

In this apparatus, a magnet is constituted using a single bulk superconductor, then, two of the magnets are placed in an opposing position, so as to form a usable space of a magnetic field. However, this apparatus has such a problem that only a small usable space having a strong magnetic field is acquired in the space between the opposing magnetic pole planes of the magnets.

Since the aforementioned bulk superconductor is synthesized by growing large crystals through special heat treatments, there is a limit in its manufacturable sizes. For instance, it is extremely difficult to synthesize a bulk superconductor (i) which has a large cross-sectional area with a diameter of, for instance, around 100 mm, while (ii) in which c-axes of its crystals are substantially aligned with each other. Accordingly, it has been extremely difficult to obtain a large magnetic field by synthesizing a single, large-sized bulk superconductor. Therefore, a large, usable space of magnetic field cannot be practically obtained with a conventional apparatus.

There is further the following problem in the conventional apparatus. The vacuum vessel containing the magnet consisting of the bulk superconductor is inseparably integrated with the freezer. Therefore, when magnetization is done of the bulk superconductor by applying a static magnetic field generated by a superconductor coil, normal operation of a motor constituting the freezer may be hindered by the influence of the magnetic field. As a result, the motor stops its rotation, so cooling cannot be done.

Patent Document 2 discloses an asymmetrical superconducting magnet apparatus that (i) has a magnet structure in which a plurality of bulk superconductors are arranged in parallel with each other so as to offer a common magnetic-pole plane, (ii) is cooled by a cooling part of a freezer, and (iii) functions as a magnet after magnetization. As the bulk superconductors in this apparatus are not placed in an opposing position, the resultant magnetic field is steeply attenuated at a location distant from, and in the direction perpendicular to, the common magnetic-pole plane from which a magnetic field is generated, thus entailing such a problem that the resultant, usable space having a strong magnetic field is small.

As described above, even when a magnet is composed of a plurality of the bulk superconductors which are arranged such that the magnetic-pole planes of the bulk superconductors are placed in a single plane, a significant attenuation of magnetic field occurs along a distance in a direction perpendicular to the plane, therefore it is extremely difficult to maintain a strong magnetic field at a position distant from the magnetic pole planes. Thus any of the prior arts has such a problem that the usable space having a strong magnetic field formed by the bulk superconductors is small.

[Patent Document 1]:

Japanese Unexamined Published Patent Document No. 2001-68338 (Pages 2, 3 and 4, and FIG. 1)

[Patent Document 2]:

Japanese Unexamined Published Patent Document No. H 11-97231 (Page 2, and FIG. 1)

### DISCLOSURE OF THE INVENTION

The present invention is made in view of the above problem that is common among the aforementioned prior arts. An object of the present invention is to provide an apparatus generating a magnetic field, that magnetize bulk superconductors into pseudo-permanent magnets, which offer a large, usable space having a strong magnetic field.

For the purpose of achieving the aforementioned object, Claim 1 of the present invention provides a superconducting permanent magnet apparatus, comprising:

(1) a composite bulk which is composed of bulk superconductor(s), each comprising a magnetic pole plane, that are held in a vacuum vessel in a thermally insulated condition, and that become magnets by capturing a magnetic field in a superconductive condition,

(2) at least one pair of said vacuum vessels that are positioned at such a distance that the magnetic field generated from said composite bulk s in each of said vacuum vessels affects each other, thus making a composite magnetic field,

(3) a vacuumizing apparatus for vacuumizing said vacuum vessel,

(4) a cooling apparatus for cooling said bulk superconductors below the superconductivity transition temperature so that said bulk superconductors are in superconductive condition, and

(5) a magnetizing coil generating a magnetic field for magnetizing said bulk superconductors, said magnetizing coil either being a superconductor coil, or being a cupper coil generating a pulse magnetic field,

(6) wherein, each of said composite bulks is composed of a plurality of said bulk superconductors being arranged substantially in parallel with each other.

According to this invention, the total area of magnetic pole planes in a composite bulk can be enlarged by arranging a plurality of bulk superconductors substantially in parallel with each other, while attenuation of magnetic field at a location distant from, and in the direction perpendicular to, the magnetic pole planes can be restrained by arranging a pair of the composite bulks to be placed opposing to each other. Accordingly, a large usable space of a strong magnetic field can be obtained. It is needless to say that an even larger space having a strong magnetic field can be formed by combining plural pairs of the composite bulks, each of the pairs being placed oppositely.

One method for magnetizing the bulk superconductors is a pulse magnetization method in which a copper coil is used. A copper coil, having a solenoidal (i.e. cylindrical) or toroidal (i.e. spiral) shape, is installed either outside or inside the vacuum vessel that contains the composite bulk. In the case of using a solenoidal coil, the composite bulk is arranged inside the solenoidal coil. In the case of using toroidal coil or coils, the composite bulk is arranged adjacent to the surface of a single toroidal coil or is arranged between two toroidal coils. A current discharged from a capacitor is applied to the copper coil(s), which generates a strong, pulse magnetic field, which is in turn applied on the bulk superconductors of the composite bulk, which are then magnetized. The copper coil—which can be devised to be downsized by restraining heat generation—may be cooled with water or liquid nitrogen. A superconductor coil may also be used instead of the copper coil.

The size of composite bulk treated in this invention is large. Thus, with the conventional method using pulse magnetization, the magnetization coil that has to contain such a composite bulk becomes large, and so the capacitor bank must be huge as well. As such, another magnetization method using a large superconducting magnet—in which the bulk superconductors are magnetized during cooling in a magnetic field generated by a superconductor coil—is desirable. This “cooling-in-magnetic-field” method enables magnetization generating a resultant magnetic field of 5 T (=Tesla) or more, thus realizing a large and strong superconducting permanent magnet.

Furthermore, Claim 2 provides a superconducting permanent magnet apparatus described in Claim 1, wherein, each of said composite bulks is constituted such that a plurality of said bulk superconductors are arranged substantially in parallel with each other, wherein the magnetic pole planes thereof are placed along a curved plane that forms a part of the surface of a cylinder or of a sphere.

According to this invention, the magnetic pole planes of the bulk superconductors are placed along a part of a circle, of a cylinder, or, of a sphere. Therefore the boundary of the usable space of magnetic field generated between the pair of said composite bulks, can take a various form substantially like a circle, like a cylinder, or like a sphere, respectively. These forms can be adopted each for its optimal usages, thus extending scope of application of the current invention.

Furthermore, Claim 3 provides a superconducting permanent magnet apparatus described either in Claim 1, or in Claim 2, wherein, each of a plurality of said bulk superconductors constituting a composite bulk, which are arranged substantially in parallel with each other, (i) is of the form of cylindrical column, or, of rectangular column, (ii) has a plurality of crystals of which c-axis is substantially aligned in the longitudinal direction of said column, and further (iii) is placed close to each other. According to this invention, the resultant magnetic field strength can be evenly distributed, so a large usable space of a uniform and strong magnetic field can be obtained.

Furthermore, Claim 4 provides a superconducting permanent magnet apparatus described either in Claim 1, or in Claim 2, or in Claim 3, wherein, said composite bulk is held, inside said vacuum vessel, with a heat insulating, structural members that are made of resin-based materials.

According to this invention, it is enabled that a heat insulating structure is provided which at the same time can endure stress acting between the opposing composite bulks. That is, the stress is very strong when the bulk superconductors are magnetized up to 5 T, either tensile in case the magnetic poles are heteropolar, while repulsive in case the magnetic poles are homopolar.

Particularly, for the purpose of holding the composite bulk in vacuum in a thermally insulated condition, the composite bulk is fixed inside the vacuum vessel using a heat-insulating member made of resin, or, of resin-based materials, which has enough strength to endure the stress acting between the composite bulks. In a detailed embodiment, as a resin material is used an FRP (fiber reinforced plastic), that is, a plastic reinforced with fiberglass.

More particularly, the aforementioned, heat-insulating resin-based structural member has a plate-like shape, is arranged around the composite bulks, and is fixed, with screws, between the parts which lead to the outside of the vacuum vessel. Even at a low temperature, the strength of FRP does not deteriorate much. Therefore, when four of FRP plates—of which cross-section perpendicular to the direction of stress is 5 mm×50 mm—are used, they can endure tensile force of up to 500 kg, while endure repulsive force of up to 100 kg. Furthermore, they show such an excellent heat-insulating performance that heat incursion is restrained, while enduring sufficiently the stresses acting between the composite bulks.

Furthermore, Claim 5 provides a superconducting permanent magnet apparatus described either in Claim 1, or in Claim 2, or in Claim 3, wherein, said cooling apparatus is constituted such that said composite bulk is thermally contacted with a cooling part of a freezer either (i) by a direct contact, (ii) via a heat conveying member, or (iii) via either one of the following: liquid nitrogen, liquid helium, gas nitrogen, and gas helium.

According to this invention, the cooling part of the freezer can provide the bulk superconductors with a lower temperature than that provided by liquid nitrogen, In such a low temperature the bulk superconductors show better superconductivity performance, hence capturing a stronger magnetic field. When the bulk superconductors are cooled, in particular by direct contact or by indirect contact via a heat conveying member with the cooling part of a freezer, the resultant cooling system is far simpler and easier to operate than the conventional one using transfer of liquid helium only.

Furthermore, Claim 6 provides a superconducting permanent magnet apparatus described in Claim 5, wherein, said freezer is an ultra-low temperature freezer (i) of which constitution is a GM type, a pulse tube type, a Stirling type, a Solvay type, or a combination of a plurality thereof, (ii) which cools and maintains said composite bulk within a temperature range between 4K and 90K in absolute temperature, and (iii) are located at such a separated position from said composite bulk that ferromagnetic members constituting said freezer can function well without being hindered by said magnetic field for magnetizing said bulk superconductors.

According to this invention, the ferromagnetic members, such as those used in a motor unit constituting the freezer, are prevented from being affected during the magnetization process of the bulk superconductors. That is, the freezer can show a regular cooling performance since the motor unit, for example, of the freezer is separated in the outside of the magnetic field generated by the superconducting magnet for magnetization of the bulk superconductors. To be more specific, in the case of a Stirling (ST) pulse type freezer, the freezer is separated in a location where magnetic field strength is reduced to 1 T or less, so that the motor is not affected by the magnetic field.

Furthermore, Claim 7 provides a superconducting permanent magnet apparatus described either in Claim 1, or in Claim 2, or in Claim 3, wherein, said cooling apparatus is constituted such that (i) said composite bulk is connected with a cooling part of a freezer via a heat conveying member which is provided in said vacuum vessel, thus (ii) said composite bulk is cooled, in a condition that thermal conduction from the outside is prevented.

According to this invention, heat can be efficiently conducted between the cooling part of a freezer and the composite bulk—both of which are at a separate position from each other in the vacuum vessel—so as to cool the composite bulk. To be more specific, the composite bulk can be cooled efficiently by connecting them with the cooling part of a freezer through a heating conveying member made of copper that has large heat conductivity.

Furthermore, Claim 8 provides a superconducting permanent magnet apparatus described either in Claim 1, or in Claim 2, wherein, each of a plurality of said bulk superconductors, further, (a) is fit with a ring that is made of one or a plurality of the following materials: stainless steel, aluminum or its alloy, copper or its alloy, synthetic resin, and fiber-reinforced resin, and (b) is placed in tight contact with said ring by using one or a plurality of the following materials: an adhesive or a resin-based filler, a grain- (or, particle-) dispersion type resin, and a fiber-reinforced resin, (i) in order to reinforce the circumference of the bulk superconductor, as well as (ii) in order to disperse heat from the bulk superconductor.

According to this invention, the bulk superconductor, which is reinforced by the ring, can have a mechanical strength, which is strong enough to endure the stress while the bulk superconductor captures a strong magnetic field. Furthermore, moisture is prevented (i) from entering into fine cracks that may exist in the bulk superconductor, thus (ii) from deteriorating the inside of the bulk superconductor.

Furthermore, Claim 9 provides a superconducting permanent magnet apparatus described either in Claim 1, or in Claim 2, or in Claim 3, wherein, each of a plurality of said bulk superconductors (a) contains (i), as a main component, a compound with a chemical expression REBa2Cu3Oy, wherein RE comprises one or a plurality of the following elements: yttrium, samarium, neodymium, europium, erbium, ytterbium, holmium, and gadolinium, (ii), as a second-phase component, 50 mol % or less of a compound with a chemical expression RE2BaCuO5, (iii) 30 weight % or less of silver, and (iv), as an additive, 0 to 10 weight % or less of platinum or cerium, then, (b) is obtained by growing a large crystal structure, using a seed crystal.

According to this invention, a bulk superconductor can be obtained that has a numerous number of strong stopper pins as well as that has a plurality of large crystals which are grown, aligned in the strongest direction of capturing magnetic field characteristics, thus that has an enough mechanical strength to endure an electromagnetic force during magnetization.

Furthermore, Claim 10 provides a superconducting permanent magnet apparatus described either in Claim 1, or in Claim 2, or in Claim 3, wherein, said vacuum vessel is vacuumized to the reduced pressure of 10⁻¹ Pa or less, by said vacuumizing apparatus, (i) which is connected with said vacuum vessel, (ii) which is either one, or combination of a plurality, of a diaphragm pipe, an oil rotating pump, a turbo molecule pump, an oil diffusion pump, a dry pump, and a cryo-pump, thus (iii) which thermally insulates by vacuum from the outside, said composite bulk within said vacuum vessel.

According to this invention, in particular by combining a low-precision type vacuum pump with a high-precision type vacuum pump, the inside of the vacuum vessel can be maintained in a condition in which an efficient thermal insulation can be realized.

The superconducting permanent magnet apparatus according to these inventions above can further comprises:

(1) a magnetic pole assembly that holds in a thermally insulated condition, said composite bulk composed of a plurality of said bulk superconductors which are arranged in parallel with each other within said vacuum vessel,

(2) a stand that (i) holds at least a plurality of said magnetic pole assemblies each in a predetermined orientation, and (ii) is movable in a condition that said magnetic pole assemblies are mounted thereon,

(3) said cooling part of said freezer being mounted on said magnetic pole assembly,

(4) said vacuumizing apparatus being a vacuum pump connected to said magnetic pole assembly via a vacuum pipe, and

(5) said composite bulk in said vacuum vessel being fixed to a flange of said magnetic pole assembly—to which said vacuum vessel is fixed—using a resin-based structural member having a heat-insulating property.

### BRIEF DESCRIPTION OF THE DRAWINGS

FIG. 1 shows an entire constitution of a superconducting permanent magnet apparatus in a first embodiment of the present invention, where (a) is a front view, (b) is a side view, and (c) is a plane view.

FIG. 2 is a cross-section view showing a structure of a magnetic pole assembly 13 of the present invention, where (a) is a front view showing a partial cross-section, and (b) is a side view.

FIG. 3 shows a constitution of a composite bulk with nine bulk superconductors, where (a) is a plane view, (b) is a A-A cross-section view of (a), while (c) is a B-B cross-section view of (a).

FIG. 4 shows a constitution of a composite bulk with four bulk superconductors, where (a) is a plane view, (b) is a A-A cross-section view of (a), while (c) is a B-B cross-section view of (a).

FIG. 5 is a plane view showing a constitution of a composite bulk with seven bulk superconductors.

FIG. 6 shows a reinforced structure of a bulk superconductor used in the present invention, where (a) is a plane view while (b) is a side cross-section view.

FIG. 7 is an explanatory figure for magnetization method of a magnetic pole assembly of the present invention.

FIG. 8 is a graph showing distribution of magnetic fields generated by a single composite bulk of the present invention.

FIG. 9 is a graph showing distribution of magnetic fields generated by an opposing pair of composite bulks of the present invention.

FIG. 10 shows a magnetic pole assembly in a second embodiment of the present invention, where (a) is a front view while (b) is a side view.

FIG. 11 is a cross-section view showing a main part of a magnetic pole assembly in a third embodiment of the present invention.

FIG. 12 shows other constitutions of a composite bulk composed of a plurality of bulk superconductors 21 that are arranged in parallel with each other, where (a) is a plane view with three in one row, (b) is a plane view with six in two rows, (c) is a plane view with three rectangular columns in one row, while (d) is a plane view with seven hexagonal columns in a closest packing, respectively, of bulk superconductors.

### DESCRIPTION OF THE PREFERRED EMBODIMENTS

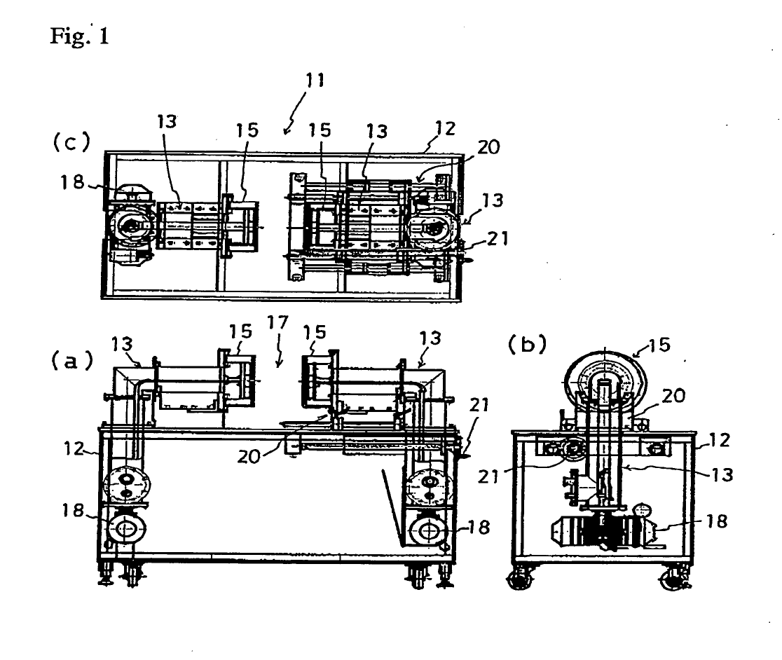

Now, embodiments of this invention will be explained in detail. FIG. 1 shows an entire constitution of a superconducting permanent magnet apparatus in a first embodiment of this invention, where (a) is a front view, (b) is a side view, and (c) is a plane view.

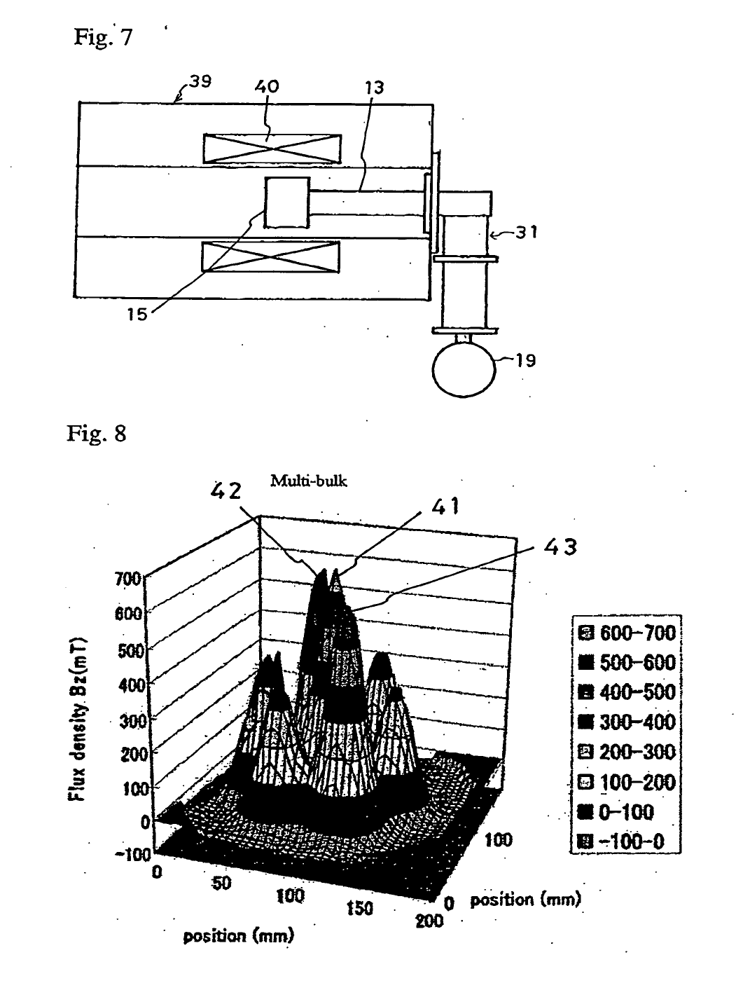

Of the superconducting permanent magnet apparatus, a magnetizing coil part—which will be explained later using FIG. 7—is not shown in FIG. 1.

In a superconducting permanent magnet apparatus 11, a pair of right and left magnetic pole assemblies 13, 13 are placed on a stand 12, so as to oppose to each other. At the top of the magnetic pole assemblies 13, 13, are respectively placed a pair of right and left vacuum vessels 15, 15. A magnetic field is to be generated in a usable space 17 between the vacuum vessels 15, 15.

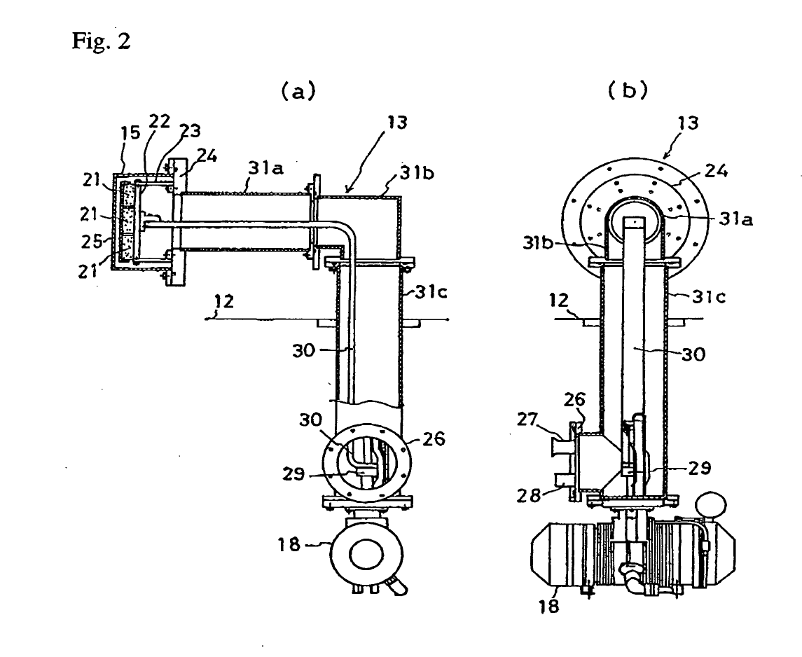

In the magnetic pole assembly 13, the vacuum vessel 15 is connected airtight with a vacuum tube 31, which consists of vacuum tubes 31a, 31b, and 31c in this sequence. On the bottom end of the vacuum tube 31c is mounted an ST pulse tube freezer 18 which cools bulk superconductors 21 (shown in FIG. 2 below) that is placed inside the vacuum vessel 15 down to a predetermined temperature.

In the stand 12 is provided a rail-and-carrier 20, of which a carrier is movable along a rail by operating a handle 20a (wrongly designated as “21” in FIG. 1). On the carrier is mounted one of the magnetic pole assemblies 13, the right-side one in the figure, so that the distance can be adjusted between the pair of the vacuum vessels 15, 15, each placed at the top of the respective magnetic pole assembly 13. By this constitution, a strong magnetic field can be generated in the large, usable space 17, which is formed between the vacuum vessels 15, 15.

FIG. 2 is a cross-section view showing a structure of a magnetic pole assembly 13 of the present invention, where (a) is a front view showing a partial cross-section, and (b) is a side view.

A composite bulk 22, consisting of a plurality of bulk superconductors 21 which are arranged in parallel and fixed with each other, is (i) further fixed, via a heat-insulating, resin-based structural member 23, onto a flange 24 of the vacuum tube 31a, and (ii) held in the vacuum vessel 15, which is air-tight connected with the vacuum tube 31 a also at the flange 24.

Each of a plurality of the bulk superconductors 21 is manufactured as a pseudo-monocrystal, of which c-axes are substantially aligned in one direction, so the distribution of a magnetic field, which is captured by the bulk superconductors 21, is nearly of a cone shape. The plurality of the bulk superconductors 21 are arranged in such a manner that the c-axes thereof are aligned with each other in the same direction perpendicular to a vacuum vessel surface 25 of the vacuum vessel 15, the surface 25 being in parallel with a common plane, on which are located magnetic pole planes of the bulk superconductors, thus constituting the composite bulk 22.

Here, the distance from the common plane, that is, from the magnetic pole planes of the bulk superconductors 21 to the vacuum vessel surface 25 is designed to be between 3 mm to 20 mm, so that a magnetic field generated by the bulk superconductors 21 is effectively extended to the outside of the vacuum vessel surface 25.

At the bottom of the magnetic pole assembly 13, the vacuum tube 31c is provided with a vacuum flange 26, on which is mounted a vacuum port 27, which in turn is connected, via a vacuum pipe, with a vacuum pump (not shown) as an example of a vacuumizing apparatus. Pressure inside the magnetic pole assembly 13 is reduced to 1×10⁻¹ Pa (Pascal) or less by the vacuum pump that is connected with the vacuum port 27, so that the inside of the magnetic pole assembly is maintained in a vacuum thermal insulation. On the vacuum flange 26 is mounted also a sensor electrode 28, which picks up signals from a thermometer and from a magnetic field sensor (a Hall-effect sensor), mounted in the inside.

The ST pulse freezer 18, having a cooling part 29, is mounted on the vacuum tube 31c such that, the cooling part 29 is located inside the vacuum tube 31c in a sealed condition. The ST pulse freezer 18 can be operated with an AC power source of 100 V, then, the cooling part 29 of the freezer 18 is cooled down to 60K.

The cooling part 29 (also called “cold head”) is connected with the composite bulk 22 in the vacuum vessel 15 via a heat conveying member 30, so that thermal conduction is done to achieve a cooling action of the freezing part 29.

Here, the heat conveying member 30, which is accommodated in the vacuum tube 31, is also held in a vacuum thermal insulation against the outside, so that the composite bulk 22 can be efficiently cooled. Taking into consideration thermal conductivity, the heat conveying member 30 is made of copper, then is gold plated thereon in order to make it corrosion resistant, as well as to prevent heat radiation from the outside.

When the bulk superconductors 21 are magnetized, then are placed in an opposing position, a strong tensile or repulsive force acts between the composite bulks 22. The tensile force acts between the magnetic poles of the different polarity, while the repulsive force acts between those of the same polarity. Accordingly, in order to hold the composite bulk 22—which have a plurality of bulk superconductors 21—in the vacuum vessel 15, it is necessary that the composite bulk 22 are strongly fixed with a heat-insulating, stout member. Fixing structure of the composite bulk will be described in detail below.

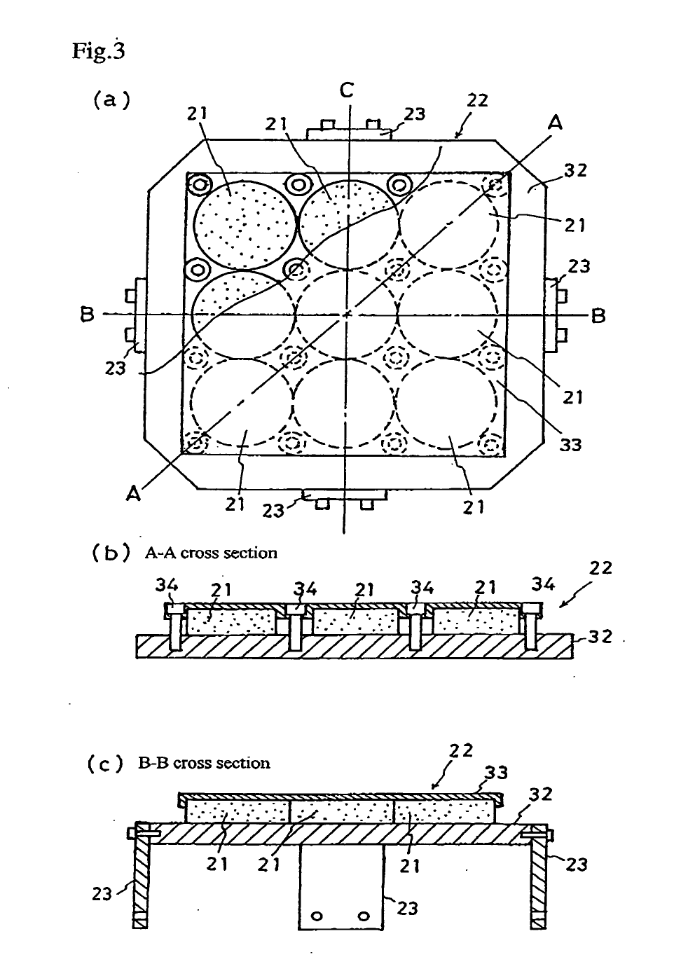

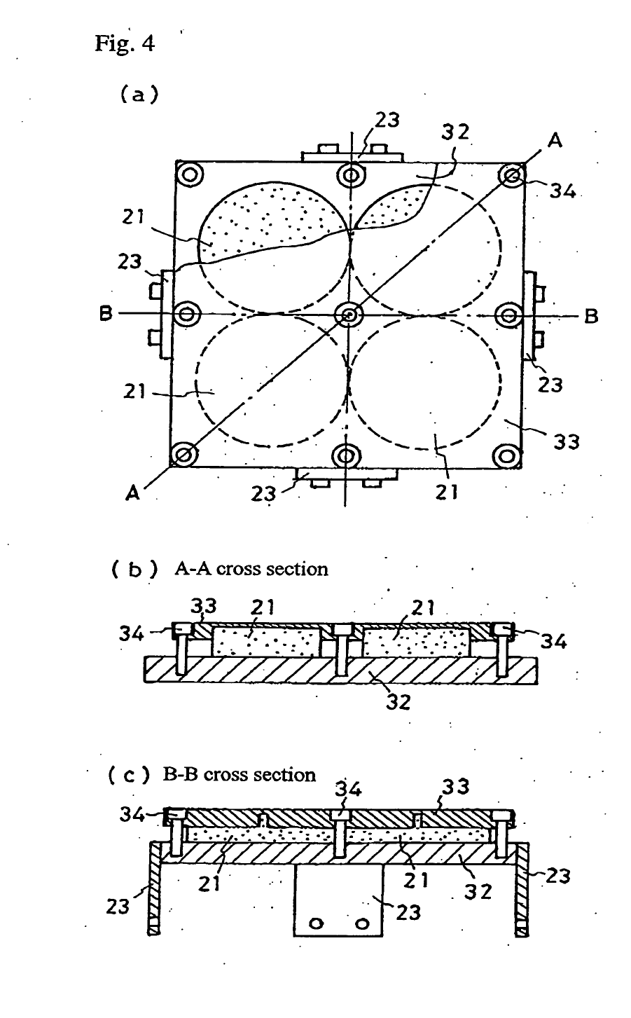

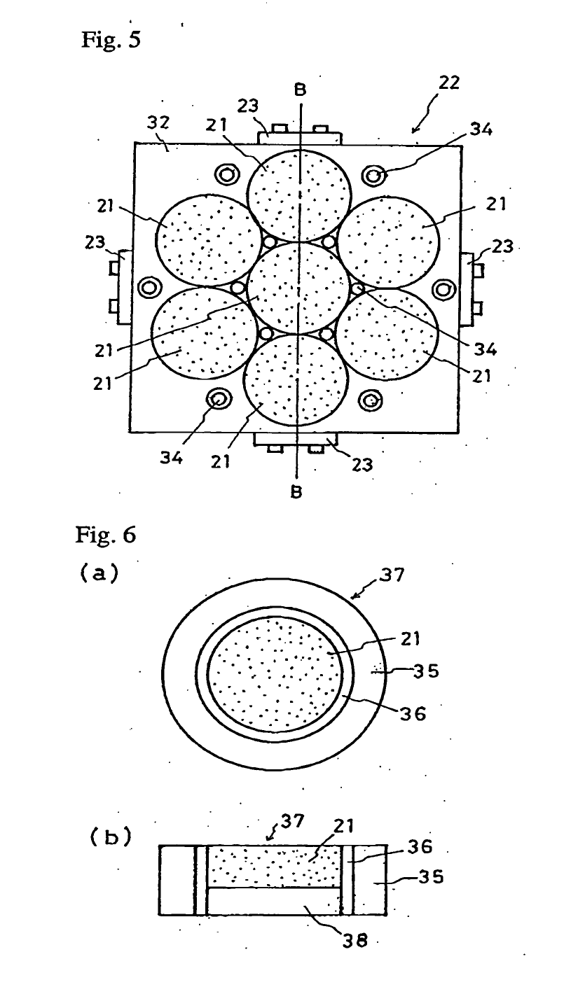

FIGS. 3, 4 and 5 show each a constitution of the composite bulk 22, in which a plurality of bulk superconductors 21 are arranged in parallel with each other. FIG. 3(a) is a plane view in the case where there are nine bulk superconductors, FIG. 3(b) is a cross-section view taken along a line A-A of FIG. 3(a), while FIG. 3(c) is a cross-section view taken along a line B-B of FIG. 3(a). FIG. 4(a) is a plane view in the case of four bulk superconductors, FIG. 4(b) is a cross-section view taken along a line A-A of FIG. 4(a), while FIG. 4(c) is a cross-section view taken along a line B-B of FIG. 4(a). FIG. 5 is a plane view in the case of seven bulk superconductors. Here a holder plate 33 is partially shown in the plane views of FIGS. 3(a), 4(a), and 5.

As is explained above using FIGS. 2 to 5, according to the present invention, the composite bulk 22 is fixed to the flange 24—to which is fixed also the vacuum vessel 15—via the heat-insulating resin-based structural member 23. To be more specific, as is shown in FIGS. 3, 4 and 5, four of the resin-based structural member 23, which is plate-formed, made of fiber-reinforced-plastic (FRP), are arranged around the composite bulk 22, and fixed to the flange 24 with screws. The four FRP plates 23 can endure an attractive force of up to 500 kg and a repulsive force of up to 100 kg, a sufficient performance that shows endurability against the force generated between the pair of composite bulks 22.

In FIGS. 3, 4 and 5, a magnet stand 32 is composed mainly of copper for thermal conduction. Furthermore the magnet stand 32 is gold plated, so that the magnet stand is corrosion resistant, while so that heat radiation from the outside is prevented. The bulk superconductors 21—onto the back side of which an indium foil is attached—are fixed to the magnet stand 32 by a holder plate 33 with screws 34.

Thus the bulk superconductors are cooled with heat being conveyed via the magnet stand 32 to the heat conveying member 30, while they are held in vacuum thermal insulation by the four resin-based structural members 23, which are fixed at a side to the magnet stand 32, while are fixed at the other side to the flange 24 with screws.

FIG. 6 shows a reinforced structure of a bulk superconductor 21 used in the present invention, where (a) is a plane view, while (b) is a side cross-section view. In order that the bulk superconductor may not be broken due to (i) thermal expansion during cooling and (ii) an electromagnetic force when capturing a magnetic field during magnetization, the bulk superconductor is mechanically reinforced such that the bulk superconductor 21 is embedded inside a stainless steel ring 35, a low-temperature resin-based filling adhesive 36 being filled between, as a result constituting a bulk superconductor magnet 37.

Actually, it is preferable that every bulk superconductor 21 is replaced by such a bulk superconductor magnet 37 as is shown in FIG. 6. For example in FIG. 3, it is preferable that the bulk superconductor magnets 37 shown in FIG. 6 are arranged in parallel with each other, rather than that only the bulk superconductors 21 are directly arranged in parallel with each other.

Coating the bulk superconductor 21 with the low-temperature resin-based filling adhesive 36 has another effect of preventing moisture from entering inside the bulk superconductor 21, said moisture being caused by dew condensation.

Concerning the stainless steel ring 35, a ring made of such a material other than stainless steel can exhibit a similar effect of mechanical reinforcement to the one stainless steel can exhibit, as aluminum or its alloy, copper or its alloy, synthetic resin, or, fiber-reinforced resin (FRP).

As a low-temperature resin-based filling adhesive 36, the following can be used: a resin-based filler, a dispersed-particle type resin, or, fiber-reinforced resin (FRP). Furthermore, when the length of the stainless steel ring 35 does not match with that of the bulk superconductor 21, a stainless steel plate 38, of which diameter is substantially equal to that of the bulk superconductor 21 and of which thickness is 0.2 mm to 5 mm, may be embedded in a similar manner to the one in which the bulk semiconductor 21 is embedded, in a back side of the bulk superconductor 21.

FIG. 7 is an explanatory figure for magnetization method of a magnetic pole assembly of the present invention. Referring to FIG. 7, a method of magnetization in one embodiment of a superconducting permanent magnet apparatus of this invention will be explained.

First, the part of the magnetic-pole assembly 13, which contains the bulk superconductors 21, is inserted into and fixed in a bore of a superconducting magnet 39. (The diameter of the bore used here is 300 mm.) At this time, the location of the magnetic pole assembly 13 is adjusted so that the bulk superconductors 21 in the vacuum vessel 15 are positioned at an approximate center of a superconductor coil 40. This does not apply, however, when the bulk superconductors 21 are to be magnetized with a lower magnetic field, or with a gradient-distributed magnetic field of the superconductor coil.

Next, a vacuum pump (not shown), which is connected to the magnetic pole assembly 13, is operated, so that the inside of the magnetic pole assembly 13, that is, the inside of the vacuum vessel 15, is maintained in a vacuum thermal insulation.

Next, the superconducting magnet 39 is operated, so that a predetermined magnetic field—a magnetic field strength of 5 T (Tesla), for example—is generated. An ST pulse freezer 19 is operated, so that the composite bulk 22 is cooled below a critical temperature of the bulk superconductors 21. In the case of this equipment, the composite bulk is cooled down to 60K, whereas in the case of a GM cycle freezer, the composite bulk 22 is cooled down to 40K, while in the case of a GM pulse tube freezer, down to about 50K.

After the composite bulk 22 is cooled down to a predetermined temperature below a superconducting transition temperature, the magnetic field by the superconducting magnet 39 is quasistatically lowered, returning to a zero magnetic field. At this time, the bulk superconductors 21 capture a magnetic field, so magnetization is completed.

The static magnetic field by the superconducting magnet 39 may have a bad influence on the operation of the motor of the freezer 19. That is, when the motor is placed too close to the bore, rotation of the motor comes to a halt. For example, in case of a voice coil type motor of the freezer 19, a magnetic circuit is formed using magnetic members; so there occurs a problem that the strong magnetic field by the superconducting magnet 39 may disturb the magnetic circuit.

Therefore, according to the present invention, the vacuum tube 31 is formed to have a predetermined length so that the motor of the freezer 19 is isolated at a distance where the magnetic field by the superconducting magnet 39 does not have any serious influence on the operation of the motor. As a result of an experiment applying a variety of strengths of magnetic field on a motor, the following is decided. The motor must be placed in an area with a magnetic-field strength of 1 T or less, which does not hinder the rotation of the motor, so the motor must be arranged at a position to be separated by 500 mm or more from the end of the superconducting magnet 39 in a direction perpendicular to the axis of the bore. For that purpose, the vacuum tube 31 of the magnetic pole assembly 13 is extended in such a way that the influence of the magnetic field are minimized.

In this manner, the magnetic pole assembly 13 having in it the composite bulk 22—which is magnetized by the magnetic field of 5 T—is pulled out from the superconducting magnet 39, then is mounted on the stand 12. Similarly, another magnetic pole assembly 13, which is to make the opposite pole, is also magnetized, and mounted on the stand 12. Thus, by placing the two large, composite bulks 22, 22 so as to be opposed with each other, a large usable space of magnetic field can be generated. The superconducting magnet 39, which is capable of applying a strong magnetic field as large as 5 T upon a composite bulk 22 with a diameter as large as 30 cm, often occupies as huge a space as that of a room. However, the stand 12 with the magnetic pole assemblies 13, 13 thereon by this invention can be made handy and easily movable because the stand 13 need not carry the superconducting magnet 39 once magnetization of the composite bulks 22, 22 is done.

As one of the opposing magnetic pole assemblies 13 is mounted on the rail-and-carrier 20 on the stand 12, the magnetic-field strength of the usable space 17 can be changed by moving the one on the rail-and-carrier 20 (see FIG. 1).

FIG. 8 is a graph showing a distribution of the magnetic field generated by a single composite bulk. To be more specific, the figure shows a result of measured distribution of a magnetic field radiated from the vacuum vessel 15 that contains a composite bulk 22 composed of seven superconductors 21 arranged in parallel with each other, obtained by scanning with a Hall sensor (not shown) over the vacuum vessel surface 25. The vertical axis represents the component Bz of the magnetic field, which is measured along the z-axis, that is, the direction perpendicular to the magnetic pole plane of the composite bulk 22. The distance from the magnetic pole plane of the magnetic pole 22 to the vacuum vessel surface 25 is taken to be 20 mm.

As shown in FIG. 8, the magnetic field generated by the seven bulk superconductors is precisely measured. Here, a central peak 41 is due to a magnetic field generated by gadolinium-based bulk superconductors. Although a magnetic field peak of 3.3 T is observed at the surface of the magnetic pole plane of the gadolinium-based bulk superconductors, strength of the magnetic field at a position separated by 20 mm is observed to be reduced to 0.7 T (=700 mT). Other bulk superconductors are also magnetized, showing each a performance that reflects their respective magnetic-field capturing ability. That is, two secondary peaks 42, 43 of 0.6 T close to the central peak 41 corresponds to the measured values of magnetic fields generated by the samarium-based bulk superconductors, while the remaining, four lowest peaks of about 0.3 T, by the yttrium-based bulk superconductors.

The composite bulk 22 may be magnetized either by static magnetic-field magnetization with the superconducting magnet 39, or, by pulse magnetization. However, this pulse magnetization method is not very convenient when magnetization with a level of 5 T (Tesla) or more is intended, as it becomes difficult to generate a strong magnetic field with this method, because the magnetization coil—which has to be able to accommodate the vacuum vessel containing the large composite—has a large inner diameter, which means, the size of the capacitor for the pulse magnetization has to become large. In other words, this method is effective for a comparatively weak magnetization, such as that of about 3 T.

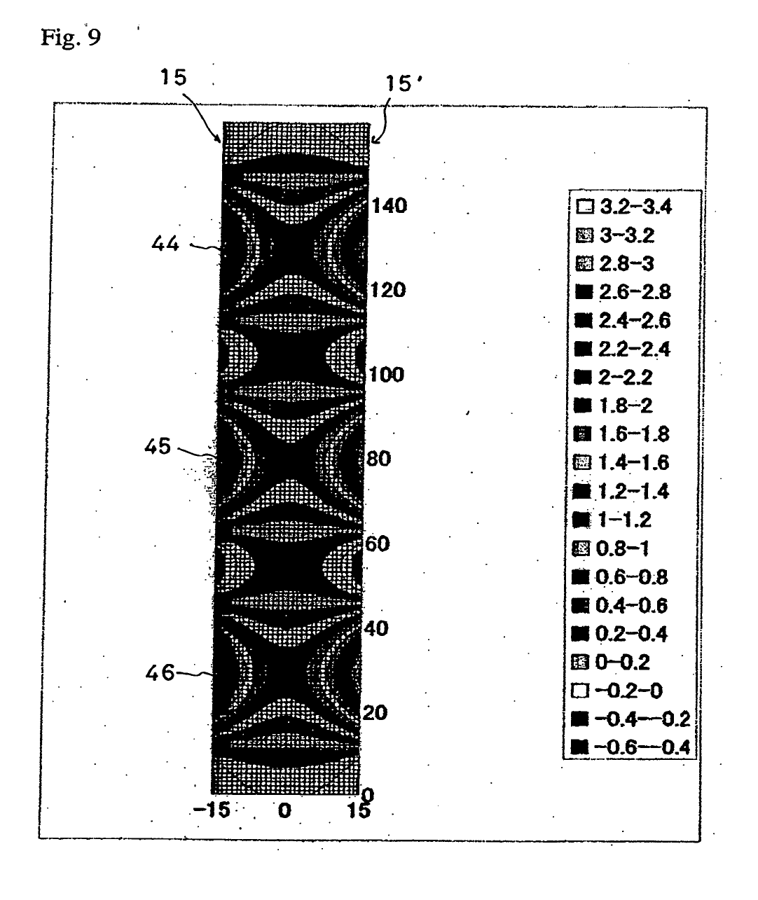

FIG. 9 is a graph showing a distribution of the magnetic field generated by the opposing pair of composite bulks. More particularly, it shows calculated result of a distribution of a magnetic field generated in the usable space 17 between the surfaces 25, 25′ (designated as 15, 15′ in FIG. 9), of the vacuum vessels 15, 15, in which, respectively, the pair of the composite bulks 22—which, in turn, are composed of seven bulk superconductors 21 respectively, arranged in parallel with each other and combined—are placed in a opposing position, after being magnetized to a different polarities. These values are calculated at positions along the line B-B either in the plane view of FIG. 3(a) where three of the bulk superconductors appear among the total of nine arranged in parallel, or, in the plane view of FIG. 5 where also three of the bulk superconductors appear among the total of seven arranged in parallel.

The magnetic field generated by the respective composite bulk 22 has a dispersed distribution including maximal peaks 44, 45, and 46, when observed at the surface of the vacuum vessel 15. These maximal peaks correspond to the three bulk superconductors 21 appearing on the line B-B constituting a part of the composite bulk 22. Similar magnetic field distribution appears when observed at the surface of the opposing vacuum vessel 15′. The pair of magnetic fields interfere with each other and grow larger, thus creating a resultant, strong magnetic field in the usable space 17 shown in FIG. 1, with a width of 30 mm in this case. Any type of application of a strong magnetic field can be realized in this usable space.

The magnetic fields of the opposing vacuum vessels 15, 15 can have the same polarity. When the opposing composite bulks are magnetized to have the same polarity, the magnetic field distribution becomes significantly different from what is shown in FIG. 9. The magnetic fields generated by the opposing composite bulks repel each other, therefore, near at the center of the usable space, the direction of the resultant magnetic field is drastically changed from a parallel one to a perpendicular one, both referring to the z-axial direction. Therefore, in the usable space 17 where the opposing composite bulks influence on each other, magnetic field strength becomes stronger along the vacuum vessel surfaces than along the direction perpendicular to the surface.

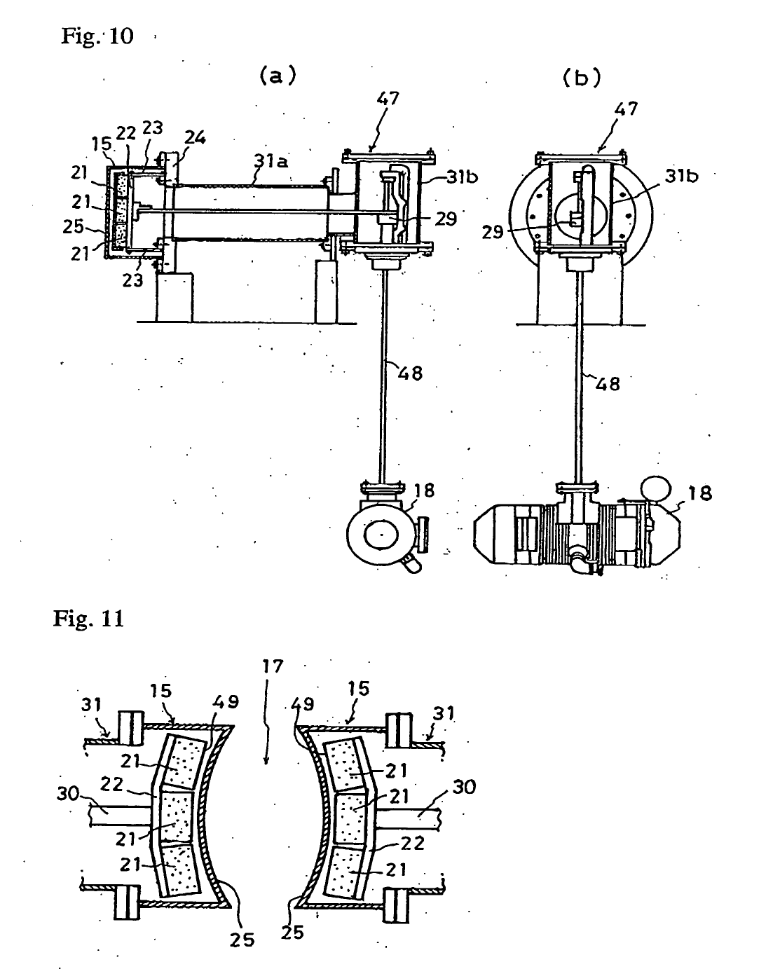

Now, a second embodiment of the present invention will be explained. FIG. 10 shows a magnetic pole assembly in a second embodiment of the present invention, where (a) is a front view, while (b) is a side view. Unlike the first embodiment, the vacuum tube 31 does not extend to the motor portion of the freezer 18, so the freezing part 29 is positioned being separated from the motor portion of the freezer 18. The motor portion and the freezing part 29 of the freezer 18 are connected with a thin pipe 48, so that the freezing part 29 is cooled, resulting in obtaining the same effect as that of the first embodiment.

Now, a third embodiment will be explained. FIG. 11 is a cross-section view showing a main part of a magnetic pole assembly in a third embodiment. It is not necessary that magnetic pole planes 49 are strictly aligned on the same plane, as is shown in the first embodiment, but it is only necessary that an effective magnetization be done with a magnetic field generated by a single superconducting magnet 39 (not shown).

In the third embodiment, therefore, magnetic pole planes 49 of the bulk superconductors 21, which constitute the composite bulk 22, may be arranged along a smoothly curved plane like the surface of a cylinder or of a sphere. In this case, as the resultant magnetic field is oriented in some degree to the center of the usable space 17, a rotating machine can be constructed by placing an armature of a rotator, for example, in the usable space 17.

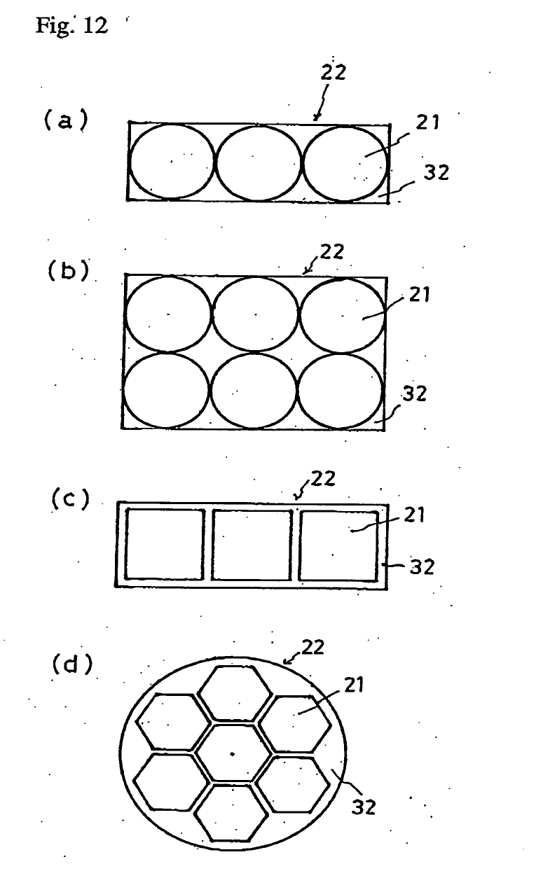

Now, a fourth embodiment will be explained. FIG. 12 shows plane views for other varieties of arrangement of bulk superconductors 21, in parallel with each other, thus composing a composite bulk. FIG. 12(a) is a plane view for a single-in-line arrangement, (b) is a plane view for a rectangular arrangement, (c) is a plane view for a single-in-line arrangement using a rectangular (square) column type bulk superconductors, while (d) is a plane view for a honeycomb arrangement using a hexagonal column type bulk superconductors.

Arrangement of the bulk superconductors 21 constituting the composite bulk 22 does not need to have a structure with good symmetry. A plurality of bulk superconductors can be arranged in a single line as is shown in FIG. 12(a), or in a rectangular shape as is shown in FIG. 12(b). A pair of such a composite bulk 22 can be positioned opposing each other at a distance where their respective magnetic fields influence on each other.

In this case, too, a pair of composite bulks opposing one another, consisting of bulk superconductors arranged in parallel with each other, can generate a strong magnetic field in a larger usable space than a single composite bulk can do.

Even when the bulk superconductors 21 are not of a cylindrical but a rectangular column shape, as is shown in FIG. 12(c), they can have a similar effect. Also, the bulk superconductors 21 can be processed into a form of a hexagonal column shape, then, seven of such bulk superconductors can be combined together to make a honeycomb-like arrangement. FIG. 12(d) shows an example thereof.

When a pair of such composite bulks as are shown in FIG. 12 are magnetized to have different polarities, then placed opposing to each other, a more uniform magnetic field distribution can be obtained than in case of a pair of composite bulks as are shown in FIG. 9, so that a strong, uniform magnetic field space 17 can be obtained in a larger usable space. Or, when the pair of composite bulks are magnetized to have the same polarity, then opposing to each other, the magnetic field strength in the direction perpendicular to the magnetic pole plane can be stronger and more uniform than in other cases—for example, in case of the arrangement shown in FIG. 4(b).

As is described above, an innovative apparatus generating a strong magnetic field can be provided by constituting and magnetizing the composite bulk that comprises the bulk superconductors according to this invention.

### INDUSTRIAL APPLICABILITY

When compared with a conventional apparatus generating a magnetic field having a single bulk superconductor, the superconducting permanent magnet apparatus, that is, the apparatus generating a magnetic field by the present invention, can provide an increased, usable space of a strong and effective magnetic field. In addition, magnetization by “cooling-in-magnetic-field” method can offer a bulk superconductor generating a still stronger magnetic field than the one by pulse magnetization method.

Furthermore, when a small-size freezer is selected, the freezer can be driven not by a commercial power source but with a mobile or built-in power supply unit that can be mounted on the freezer, such as an uninterruptible power supply unit. Therefore, this apparatus generating a magnetic field can be used not only as equipment installed indoors, but also as one installed outdoors.

1. A superconducting permanent magnet apparatus, comprising:
a composite bulk having one or more bulk superconductor(s) that are held in a vacuum vessel in a thermally insulated condition, and that become magnets by capturing a magnetic field in a superconductive condition,
at least one pair of said vacuum vessels that are positioned at such a distance that the magnetic field generated from said composite bulks in each of said vacuum vessels affects each other, thus making a composite magnetic field,
a vacuumizing apparatus for vacuumizing said vacuum vessels,
a cooling apparatus for cooling said bulk superconductors below the superconductivity transition temperature so that said bulk superconductors are in superconductive condition,
a magnetizing coil generating a magnetic field for magnetizing said bulk superconductors, said magnetizing coil either being a superconductor coil, or being a cupper coil generating a pulse magnetic field,
wherein, each of said composite bulks is composed of a plurality of said bulk superconductors being arranged substantially in parallel with each other.

2. The superconducting permanent magnet apparatus described in claim 1, wherein, each of said composite bulks is constituted such that a plurality of said bulk superconductors are arranged substantially in parallel with each other, wherein the magnetic pole planes thereof are placed along a curved plane that forms a part of the surface of a cylinder or of a sphere.

3. The superconducting permanent magnet apparatus described in claim 1, wherein, each of a plurality of said bulk superconductors constituting a composite bulk, which are arranged substantially in parallel with each other, (i) is of the form of cylindrical column, or, of rectangular column, (ii) has a plurality of crystals of which c-axis is substantially aligned in the longitudinal direction of said column, and further (iii) is placed close to each other.

4. The superconducting permanent magnet apparatus described in claim 1, wherein, said composite bulk is held, inside said vacuum vessel, with a heat insulating, structural members that are made of resin-based materials.

5. The superconducting permanent magnet apparatus described in claim 1, wherein, said cooling apparatus is constituted such that said composite bulk is thermally contacted with a cooling part of a freezer either (i) by a direct contact, (ii) via a heat conveying member, or (iii) via either one of the following: liquid nitrogen, liquid helium, gas nitrogen, and gas helium.

6. The superconducting permanent magnet apparatus described in claim 5, wherein, said freezer is an ultra-low temperature freezer (i) of which constitution is a GM type, a pulse tube type, a Stirling type, a Solvay type, or a combination of a plurality thereof, (ii) which cools and maintains said composite bulk within a temperature range between 4K and 90K in absolute temperature, and (iii) are located at such a separated position from said composite bulk that ferromagnetic members constituting said freezer can function well without being hindered by said magnetic field for magnetizing said bulk superconductors.

7. The superconducting permanent magnet apparatus described in claim 1, wherein, said cooling apparatus is constituted such that (i) said composite bulk is connected with a cooling part of a freezer via a heat conveying member which is provided in said vacuum vessel, thus (ii) said composite bulk is cooled, in a condition that thermal conduction from the outside is prevented.

8. The superconducting permanent magnet apparatus described in claim 1, wherein, each of a plurality of said bulk superconductors, further, (a) is fit with a ring that is made of one or a plurality of the following materials: stainless steel, aluminum or its alloy, copper or its alloy, synthetic resin, and fiber-reinforced resin, and (b) is placed in tight contact with said ring by using one or a plurality of the following materials: an adhesive or a resin-based filler, a grain- (or, particle-) dispersion type resin, and a fiber-reinforced resin, (i) in order to reinforce the circumference of the bulk superconductor, as well as (ii) in order to disperse heat from the bulk superconductor.

9. The superconducting permanent magnet apparatus described in claim 1, wherein, each of a plurality of said bulk superconductors (a) contains (i), as a main component, a compound with a chemical expression REBa2Cu3Oy, wherein RE comprises one or a plurality of the following elements: yttrium, samarium, neodymium, europium, erbium, ytterbium, holmium, and gadolinium, (ii), as a second-phase component, 50 mol % or less of a compound with a chemical expression RE2BaCuO5, (iii) 30 weight % or less of silver, and (iv), as an additive, 0 to 10 weight % or less of platinum or cerium, then, (b) is obtained by growing a large crystal structure, using a seed crystal.

10. The superconducting permanent magnet apparatus described in claim 1, wherein, said vacuum vessel is vacuumized to the reduced pressure of 10⁻¹ Pa or less, by said vacuumizing apparatus, (i) which is connected with said vacuum vessel, (ii) which is either one, or combination of a plurality, of a diaphragm pipe, an oil rotating pump, a turbo molecule pump, an oil diffusion pump, a dry pump, and a cryo-pump, thus (iii) which thermally insulates by vacuum from the outside, said composite bulk within said vacuum vessel.

11. The superconducting permanent magnet apparatus described in claim 2, wherein, each of a plurality of said bulk superconductors constituting a composite bulk, which are arranged substantially in parallel with each other, (i) is of the form of cylindrical column, or, of rectangular column, (ii) has a plurality of crystals of which c-axis is substantially aligned in the longitudinal direction of said column, and further (iii) is placed close to each other.

12. The superconducting permanent magnet apparatus described in claim 2, wherein, said composite bulk is held, inside said vacuum vessel, with a heat insulating, structural members that are made of resin-based materials.

13. The superconducting permanent magnet apparatus described in claim 3, wherein, said composite bulk is held, inside said vacuum vessel, with a heat insulating, structural members that are made of resin-based materials.

14. The superconducting permanent magnet apparatus described in claim 2, wherein, said cooling apparatus is constituted such that said composite bulk is thermally contacted with a cooling part of a freezer either (i) by a direct contact, (ii) via a heat conveying member, or (iii) via either one of the following: liquid nitrogen, liquid helium, gas nitrogen, and gas helium.

15. The superconducting permanent magnet apparatus described in claim 3, wherein, said cooling apparatus is constituted such that said composite bulk is thermally contacted with a cooling part of a freezer either (i) by a direct contact, (ii) via a heat conveying member, or (iii) via either one of the following: liquid nitrogen, liquid helium, gas nitrogen, and gas helium.

16. The superconducting permanent magnet apparatus described in claim 2, wherein, said cooling apparatus is constituted such that (i) said composite bulk is connected with a cooling part of a freezer via a heat conveying member which is provided in said vacuum vessel, thus (ii) said composite bulk is cooled, in a condition that thermal conduction from the outside is prevented.

17. The superconducting permanent magnet apparatus described in claim 3, wherein, said cooling apparatus is constituted such that (i) said composite bulk is connected with a cooling part of a freezer via a heat conveying member which is provided in said vacuum vessel, thus (ii) said composite bulk is cooled, in a condition that thermal conduction from the outside is prevented.

18. The superconducting permanent magnet apparatus described in claim 2, wherein, each of a plurality of said bulk superconductors, further, (a) is fit with a ring that is made of one or a plurality of the following materials: stainless steel, aluminum or its alloy, copper or its alloy, synthetic resin, and fiber-reinforced resin, and (b) is placed in tight contact with said ring by using one or a plurality of the following materials: an adhesive or a resin-based filler, a grain- (or, particle-) dispersion type resin, and a fiber-reinforced resin, (i) in order to reinforce the circumference of the bulk superconductor, as well as (ii) in order to disperse heat from the bulk superconductor.

19. The superconducting permanent magnet apparatus described in claim 2, wherein, each of a plurality of said bulk superconductors (a) contains (i), as a main component, a compound with a chemical expression REBa2Cu3Oy, wherein RE comprises one or a plurality of the following elements: yttrium, samarium, neodymium, europium, erbium, ytterbium, holmium, and gadolinium, (ii), as a second-phase component, 50 mol % or less of a compound with a chemical expression RE2BaCuO5, (iii) 30 weight % or less of silver, and (iv), as an additive, 0 to 10 weight % or less of platinum or cerium, then, (b) is obtained by growing a large crystal structure, using a seed crystal.

20. The superconducting permanent magnet apparatus described in claim 3, wherein, each of a plurality of said bulk superconductors (a) contains (i), as a main component, a compound with a chemical expression REBa2Cu3Oy, wherein RE comprises one or a plurality of the following elements: yttrium, samarium, neodymium, europium, erbium, ytterbium, holmium, and gadolinium, (ii), as a second-phase component, 50 mol % or less of a compound with a chemical expression RE2BaCuO5, (iii) 30 weight % or less of silver, and (iv), as an additive, 0 to 10 weight % or less of platinum or cerium, then, (b) is obtained by growing a large crystal structure, using a seed crystal.

21. The superconducting permanent magnet apparatus described in claim 2, wherein, said vacuum vessel is vacuumized to the reduced pressure of 10⁻¹ Pa or less, by said vacuumizing apparatus, (i) which is connected with said vacuum vessel, (ii) which is either one, or combination of a plurality, of a diaphragm pipe, an oil rotating pump, a turbo molecule pump, an oil diffusion pump, a dry pump, and a cryo-pump, thus (iii) which thermally insulates by vacuum from the outside, said composite bulk within said vacuum vessel.

22. The superconducting permanent magnet apparatus described in claim 3, wherein, said vacuum vessel is vacuumized to the reduced pressure of 10⁻¹ Pa or less, by said vacuumizing apparatus, (i) which is connected with said vacuum vessel, (ii) which is either one, or combination of a plurality, of a diaphragm pipe, an oil rotating pump, a turbo molecule pump, an oil diffusion pump, a dry pump, and a cryo-pump, thus (iii) which thermally insulates by vacuum from the outside, said composite bulk within said vacuum vessel.
